(19) United States
(12) Patent Application Publication
(10) Pub. No.: US 2022/0229475 A1
(43) Pub. Date: Jul. 21, 2022

(54) WATER BLOCK OF DOUBLE-LAYERED RADIATING WATER-COOLING RADIATOR

(71) Applicant: BEIJING DEEPCOOL INDUSTRIES CO., LTD., Beijing (CN)

(72) Inventor: Weichao LI, Beijing (CN)

(21) Appl. No.: 17/715,981

(22) Filed: Apr. 8, 2022

Related U.S. Application Data
(63) Continuation of application No. PCT/CN2020/116521, filed on Sep. 21, 2020.

(30) Foreign Application Priority Data
Nov. 20, 2019 (CN) 201911141246.X

(51) Int. Cl. G06F 1/20; H05K 7/20

(52) U.S. Cl. CPC G06F 1/20; G06F 2200/201; H05K 7/20272; H05K 7/20263

(57) ABSTRACT

A water block of a double-layered radiating water-cooling radiator includes a first heat exchange area, a second heat exchange area, a motor, a first connecting pipe, a second connecting pipe and a radiating module. A cooling liquid enters the first heat exchange area from a first water inlet of the first heat exchange area, flows through the first heat exchange area, the first connecting pipe, the second heat exchange area and the second connecting pipe in sequence, flows out from a first water outlet of the first heat exchange area, flows into a water inlet of a radiating bar, flows out from a water outlet of the radiating bar, and flows into the first water inlet of the first heat exchange area, thereby forming a cooling cycle. Whereby the water block of a double-layered radiating water-cooling radiator disclosed by the present invention improves the radiating efficiency greatly.

### FIELD OF TECHNOLOGY

The present invention relates to the technical field of water-cooling radiators of computer CPUs, in particular to a water block of a double-layered radiating water-cooling radiator.

### BACKGROUND

It is well known that integrated circuits in a computer will generate plenty of heat, which will lead to unstable operation and shortened service life of a system, and is even likely to burn some components. Therefore, it is necessary to arrange a radiator to absorb the heat so as to guarantee normal temperatures of the components of the computer.

However, a liquid-cooling radiator generally used for radiation of a computer CPU performs radiation by means of circulation of a cooling liquid. The cooling liquid will take away heat at a heating end and release the heat at a radiating end, thereby achieving a radiating purpose.

A whole device in an existing scheme includes a water block, a pipeline and a radiating bar and the like. Driven by a water pump in the water block, the cooling liquid flows through assemblies such as the water block, the pipeline and the radiating bar in sequence. The device is matched with water blocks and radiating bars of different specifications according to radiating requirements. The radiating capacity is dependent on the radiating area of the radiating bar, and the larger the area is, the better the radiating capacity is.

However, subject to compatibility, in the existing scheme, the size of the radiating bar is often limited by the size of a case and arrangement of an installation site, and the radiating capacity of the system is limited by the size of the radiating bar.

Information disclosed in this background art is merely intended to enhance understanding of the general background of the present invention and shall not be taken as an acknowledgment or any form of suggestion that this information forms the prior art already known to those of ordinary skill in the art.

### SUMMARY

The present invention is intended to provide a water block of a double-layered radiating water-cooling radiator, where the water block can improve the radiating efficiency greatly.

In order to achieve the above objective, the present invention discloses a water block of a double-layered radiating water-cooling radiator. The water block includes a first heat exchange area, a second heat exchange area, a motor, a first connecting pipe, a second connecting pipe and a radiating module. The bottom of the first heat exchange area is fixed to a CPU; the second first heat exchange area is fixed to the first heat exchange area; the motor is arranged between the first heat exchange area and the second heat exchange area; the first heat exchange area and the second heat exchange area are communicated via the first connecting pipe and the second connecting pipe; and the radiating module is fixed to the top of the second heat exchange area, where a cooling liquid enters the first heat exchange area from a first water inlet of the first heat exchange area, flows through the first heat exchange area, the first connecting pipe, the second heat exchange area and the second connecting pipe in sequence, flows out from a first water outlet of the first heat exchange area, flows into a water inlet of a radiating bar, flows out from a water outlet of the radiating bar, and flows into the first water inlet of the first heat exchange area, thereby forming a cooling cycle, where the radiating module is used for radiation of the cooling liquid flowing through the second heat exchange area.

In an implementation mode of the present invention, the water block of a double-layered radiating water-cooling radiator further includes a fan fixed to the radiating module and used for radiation of the radiating module.

In an implementation mode of the present invention, the first heat exchange area includes a heat exchange copper bottom and a copper bottom bin. The bottom of the heat exchange copper bottom is fixed to the CUP for absorbing heat of the CPU, and the copper bottom bin is fixed to the heat exchange copper bottom and includes a water feeding area and a water return area, where the first water inlet and the first water outlet are formed in a side wall of the copper bottom bin.

In an implementation mode of the present invention, the second heat exchange area includes an impeller bin, an impeller, a water dividing plate and a radiating cover plate, the impeller being arranged in the impeller bin, the water dividing plate covering the impeller, the radiating cover plate covering the water dividing plate and being fixedly connected with the top of the impeller bin, the bottom of the radiating module being fixed to the top of the radiating cover plate, and the radiating cover plate being used for sealing the second heat exchange area, where the impeller bin is provided with a second water inlet and a second water outlet.

In an implementation mode of the present invention, the first heat exchange area is provided with an outer shell outside.

In an implementation mode of the present invention, the water block of a double-layered radiating water-cooling radiator further includes a water inlet nozzle and a water outlet nozzle. One end of the water inlet nozzle is fixedly connected and communicated with the first water inlet and the other end of the water inlet nozzle is communicated with the water outlet of the radiating bar, and the water outlet nozzle is fixedly connected and communicated with the first water outlet and the other end of the water outlet nozzle is communicated with the water inlet of the radiating bar.

Compared with the prior art, the water block of a double-layered radiating water-cooling radiator according to the present invention additionally provided with the radiating module and the fan without changing the specification of the radiating bar improves the radiating efficiency greatly, so that the computer system operates better.

### BRIEF DESCRIPTION OF THE DRAWINGS

FIG. 1 is an integral structural schematic diagram of a water block of a double-layered radiating water-cooling radiator according to an implementation mode of the present invention.

FIG. 2 is a breakdown structural schematic diagram of a water block of a double-layered radiating water-cooling radiator according to an implementation mode of the present invention.

FIG. 3 is a breakdown structural schematic diagram of a second heat exchange area of a water block of a double-layered radiating water-cooling radiator according to an implementation mode of the present invention.

### DESCRIPTION OF MAIN NUMERALS OF THE DRAWINGS

1—heat exchange copper bottom; 2—copper bottom bin; 21—water feeding area; 22—water return area; 23—first water inlet; 24—first water outlet; 3—impeller bin; 4—motor; 5—impeller; 6—water dividing plate; 61—water dividing sheet; 7—radiating module; 8—first connecting pipe; 9—second connecting pipe; 10—fan; 11—radiating bar; 12—outer shell; 13—water inlet nozzle; 14—water outlet nozzle; 15—radiating cover plate.

### DESCRIPTION OF THE EMBODIMENTS

Detailed description on the specific implementation modes of the present invention is made below in combination with the drawings, and it shall be understood that the scope of protection of the present invention is not limited by the specific implementation modes.

Unless otherwise expressly indicated, terms “include” or its transformation such as “comprise” or “consist of” throughout the description and claims will be understood to include stated elements or components but rather than excludes other elements or components.

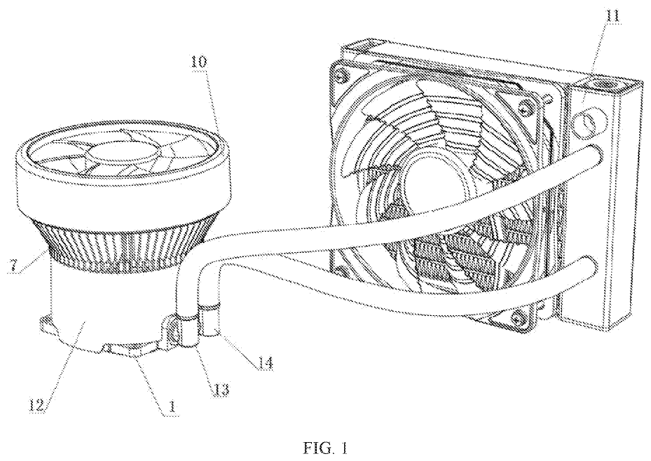

FIG. 1 is an integral structural schematic diagram of a water block of a double-layered radiating water-cooling radiator according to an implementation mode of the present invention. As shown in FIG. 1, the water block of a double-layered radiating water-cooling radiator according to a preferred implementation mode of the present invention includes a first heat exchange area, a second heat exchange area, a motor 4, a first connecting pipe 8, a second connecting pipe 9 and a radiating module 7. The bottom of the first heat exchange area is fixed to a CPU; the second first heat exchange area is fixed to the first heat exchange area; the motor 4 is arranged between the first heat exchange area and the second heat exchange area; the first heat exchange area and the second heat exchange area are communicated via the first connecting pipe 8 and the second connecting pipe 9; and the radiating module 7 is fixed to the second heat exchange area, where a cooling liquid enters the first heat exchange area from a first water inlet 23 of the first heat exchange area, flows through the first heat exchange area, the first connecting pipe 8, the second heat exchange area and the second connecting pipe 9 in sequence, flows out from a first water outlet 24 of the first heat exchange area, flows into a water inlet of a radiating bar 11, flows out from a water outlet of the radiating bar 11, and flows into the first water inlet 23 of the first heat exchange area, thereby forming a cooling cycle, where the radiating module 7 is used for radiation of the cooling liquid flowing through the second heat exchange area; and the water block of a double-layered radiating water-cooling radiator further includes a fan 10 fixed to the radiating module 7 and used for radiation of the radiating module 7, where the first heat exchange area is provided with an outer shell 12 outside.

As shown in FIG. 1, in an implementation mode of the present invention, the water block of a double-layered radiating water-cooling radiator further includes a water inlet nozzle 13 and a water outlet nozzle 14. One end of the water inlet nozzle 13 is fixedly connected and communicated with the first water inlet 23 and the other end of the water inlet nozzle 13 is communicated with the water outlet of the radiating bar 11, and the water outlet nozzle 14 is fixedly connected and communicated with the first water outlet 24 and the other end of the water outlet nozzle 14 is communicated with the water inlet of the radiating bar 11.

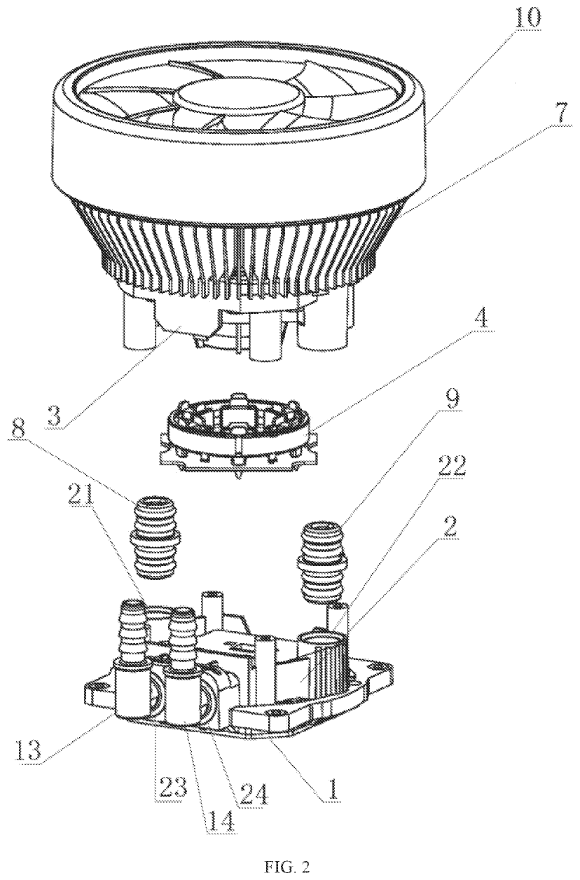

FIG. 2 is a breakdown structural schematic diagram of a water block of a double-layered radiating water-cooling radiator according to an implementation mode of the present invention. As shown in FIG. 2, in an implementation mode of the present invention, the first heat exchange area includes a heat exchange copper bottom 1 and a copper bottom bin 2. The bottom of the heat exchange copper bottom 1 is fixed to the CUP for absorbing heat of the CPU, and the copper bottom bin 2 is fixed to the heat exchange copper bottom 1 and the copper bottom bin 2 includes a water feeding area 21 and a water return area 22, where the first water inlet 23 and the first water outlet 24 are formed in a side wall of the copper bottom bin 2.

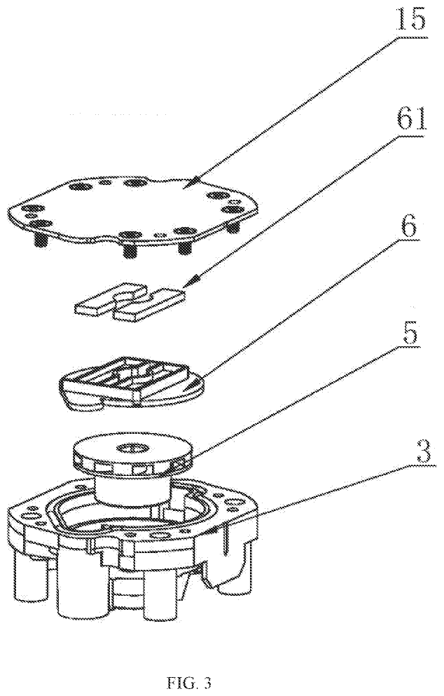

FIG. 3 is a breakdown structural schematic diagram of a second heat exchange area of a water block of a double-layered radiating water-cooling radiator according to an implementation mode of the present invention. As shown in FIG. 3, in an implementation mode of the present invention, the second heat exchange area includes an impeller bin 3, an impeller 5, a water dividing plate 6, water dividing sheets 61 and a radiating cover plate 15, where the motor 4 is arranged on a lower portion of the impeller bin 3, the impeller 5 is arranged in the impeller bin 3, the water dividing plate 6 covers the impeller 5, the water dividing sheets 61 are arranged on the water dividing plate 6, the radiating cover plate 15 covers the water dividing plate 6 and fixedly connected with the top of the impeller bin 3, the bottom f the radiating module 7 is fixed to the top of the radiating cover plate 15, and the radiating cover plate 15 is used for sealing the second heat exchange area.

In an actual application, according to the water block of a double-layered radiating water-cooling radiator, the cooling liquid in the first heat exchange area contacts with the heat exchange copper bottom 1 and absorbs heat transferred by the CPU to the heat exchange copper bottom 1, so that the cooling liquid with the heat flows to the second heat exchange area via the water feeding area 21 and the first connecting pipe 8. When the cooling liquid passes through the second heat exchange area, the radiating module 7 and the fan 10 perform radiation on the cooling liquid (first-time radiation on the cooling liquid is performed in the second heat exchange area), thereby, the radiating area can be increased by means of the arrangement without changing the specification of the radiating bar 11. The radiated cooling liquid flows to the water inlet of the radiating bar 11 via the impeller 5, the impeller bin 3, the second connecting pipe 9, the water return area 22, the first water outlet 24 and the water outlet nozzle 14, and the cooling liquid radiated by the radiating bar 11 flows back to the copper bottom bin 2 via the water inlet nozzle 13 and the first water inlet 23 (second-time radiation on the cooling liquid passing through is performed by the radiating bar 11), thereby forming a cooling cycle.

In conclusion, the water block of a double-layered radiating water-cooling radiator according to the present invention increases the radiating area without changing the specification of the radiating bar and improves the radiating efficiency greatly, so that the computer system operates better.

The above specific exemplary embodiments of the present invention are described for purposes of example illustration and description. These descriptions are not intended to limit the invention to the precise forms disclosed, and obviously many modifications and variations are possible in light of the above teaching. The exemplary embodiments are chosen and described in order to explain certain principles of the invention and their practical applications, thereby, enabling those skilled in the art to make and utilize various exemplary embodiments of the present invention, as well as various different alternatives and modifications thereof. The scope of the present invention is intended to be defined by the claims and equivalents thereof

What is claimed is:

1. A water block of a double-layered radiating water-cooling radiator, the water block comprising:
a first heat exchange area, the bottom of the first heat exchange area being fixed to a CPU;
a second first heat exchange area, fixed to the top of the first heat exchange area;
a motor, arranged between the first heat exchange area and the second heat exchange area;
a first connecting pipe and a second connecting pipe; the first heat exchange area and the second heat exchange area being communicated via the first connecting pipe and the second connecting pipe; and
a radiating module; fixed to the top of the second heat exchange area;
wherein a cooling liquid enters the first heat exchange area from a first water inlet of the first heat exchange area; flows through the first heat exchange area, the first connecting pipe, the second heat exchange area and the second connecting pipe in sequence, flows out from a first water outlet of the first heat exchange area, flows into a water inlet of a radiating bar, flows out from a water outlet of the radiating bar, and flows into the first water inlet of the first heat exchange area, thereby forming a cooling cycle;
wherein the radiating module is used for radiation of the cooling liquid flowing through the second heat exchange area.

2. The water block of a double-layered radiating water-cooling radiator of claim 1, further comprising a fan fixed to the radiating module and used for radiation of the radiating module.

3. The water block of a double-layered radiating water-cooling radiator of claim 1, wherein the first heat exchange area comprises:
a heat exchange copper bottom, the bottom of the heat exchange copper bottom being fixed to the CUP for absorbing heat of the CPU; and
a copper bottom bin being fixed to the heat exchange copper bottom and comprising a water feeding area and a water return area;
wherein the first water inlet and the first water outlet are formed in a side wall of the copper bottom bin.

4. The water block of a double-layered radiating water-cooling radiator of claim 1, wherein the second heat exchange area comprises an impeller bin, an impeller, a water dividing plate and a radiating cover plate, the impeller being arranged in the impeller bin, the water dividing plate covering the impeller, the radiating cover plate coveting the water dividing plate and being fixedly connected with the top of the impeller cabin; the bottom of the radiating module being fixed to the top of the radiating cover plate, and the radiating cover plate being used for sealing the second heat exchange area;
wherein the impeller bin is provided with a second water inlet and a second water outlet.

5. The water block of a double-layered radiating water-cooling radiator of claim 1,
wherein the first heat exchange area is provided with an outer shell outside.

6. The water block of a double-layered radiating water-cooling radiator of claim 1, further comprising:
a water inlet nozzle, one end of the water inlet nozzle being fixedly connected and communicated with the first water inlet and the other end of the water inlet nozzle being communicated with the water outlet of the radiating bar, and
a water outlet nozzle being fixedly connected and communicated with the first water outlet and the other end of the water outlet nozzle being communicated with the water inlet of the radiating bar.
